(19) United States
(12) Patent Application Publication
(10) Pub. No.: US 2015/0021671 A1
(43) Pub. Date: Jan. 22, 2015

(54) FIELD-EFFECT TRANSISTOR AND METHOD OF MANUFACTURING THEREOF

(71) Applicant: SHARP KABUSHIKI KAISHA, Osaka-shi, Osaka (JP)

(72) Inventors: Tetsuzo Nagahisa, Osaka-shi (JP); Shinichi Handa, Osaka-shi (JP)

(21) Appl. No.: 14/354,996

(22) PCT Filed: Oct. 5, 2012
(86) PCT No.: PCT/JP2012/076033

§ 371 Date: Apr. 29, 2014

(30) Foreign Application Priority Data
Nov. 14, 2011 (JP) 2011-248222

(51) Int. Cl. H01L 29/78; H01L 29/66

(52) U.S. Cl. CPC H01L 29/78; H01L 29/66522
USPC 257/288; 438/285

(57) ABSTRACT

According to this GaN-based HFET, resistivity ρ of a semi-insulating film forming a gate insulating film is 3.9×10⁹ Ωcm. The value of this resistivity ρ is a value derived when the current density is 6.25×10⁻⁴ (A/cm²). By inclusion of the gate insulating film by a semi-insulating film having a resistivity ρ=3.9×10⁹ Ωcm, a withstand voltage of 1000 V can be obtained. Meanwhile, the withstand voltage abruptly drops as the resistivity of the gate insulating film exceeds 1×10¹¹ Ωcm, and the gate leak current increases when the resistivity of the gate insulating film drops below 1×10⁷ Ωcm.

### TECHNICAL FIELD

The present invention relates to an HFET (Heterojunction Field-Effect Transistor) of, for example, MIS (Metal Insulator Semiconductor) structure, and to a manufacturing method thereof.

### BACKGROUND ART

As an HFET of MIS structure, conventionally, a GaN-based MOSFET is disclosed in PTL1 (JP 2009-76673 A). In this GaN-based MOSFET, a p-type GaN layer is formed via an AlN buffer layer on a silicon substrate, and a gate electrode is formed via a gate insulating film on the p-type GaN layer. In this GaN-based MOSFET, a SiO₂ film having quite a high resistivity as much as 10¹² Ωcm or more is adopted as a gate insulating film.

### CITATION LIST

### Patent Literature

PTL1: JP 2009-76673 A

### SUMMARY OF INVENTION

### Technical Problem

However, in the conventional GaN-based MOSFET shown above, although a SiO₂ film of quite high resistivity is used as a gate insulating film, yet its withstand voltage is, for example, about 100 V, which is insufficient.

Accordingly, an object of the invention is to provide a field-effect transistor, as well as a manufacturing method thereof, which is capable of further improving its withstand voltage.

### Solution to Problem

The present inventors have found that as to the gate insulating film, using a semi-insulating film having a resistivity of 10¹¹ Ωcm or less for the gate insulating film allows the withstand voltage to be considerably improved as compared with cases where a SiO₂ film having a resistivity of 10¹² Ωcm or more is adopted, contrary to the traditional common knowledge that the withstand voltage improves increasingly with increasing resistivity.

It is an opposition to common sense that lowering the resistivity of the gate insulating film allows the withstand voltage to be improved, which was an unpredicted phenomenon for the inventors. However, it has proved by experiments performed by the present inventors that the withstand voltage is considerably improved by using a semi-insulating film having a resistivity of 10¹¹ Ωcm or less as the gate insulating film.

The present invention has been created on the basis of the empirical finding by the present inventors that using a semi-insulating film having a resistivity of 1×10¹¹ Ωcm or less as the gate insulating film as shown above allows the withstand voltage to be considerably improved.

That is, a field-effect transistor according to the present invention comprises:

a nitride semiconductor layer;

a source electrode and a drain electrode which are formed, at least partly, on the nitride semiconductor layer or within the nitride semiconductor layer and which are disposed with a distance to each other;

a gate electrode formed on the nitride semiconductor layer and disposed between the source electrode and the drain electrode; and

a gate insulating film formed between the gate electrode and the nitride semiconductor layer, wherein

the gate insulating film is

a semi-insulating film having a resistivity of 10⁷ Ωcm to 10¹¹ Ωcm.

According to the field-effect transistor of this invention, it has proved that by the feature that the resistivity of the semi-insulating film forming the gate insulating film is 10¹¹ Ωcm or less, as shown by a characteristic J in FIG. 3, the withstand voltage can be considerably improved as compared with cases where the resistivity of the gate insulating film is over 10¹¹ Ωcm.

In FIG. 3, the withstand voltage (V) in the vertical axis was given by voltage Vds (V) obtained immediately before occurrence of dielectric breakdown caused by increasing the voltage Vds between drain electrode and source electrode in steps of 50 V up to a breakdown under the conditions of 0 V applied to the source electrode and −10 V applied to the gate electrode at normal temperature (25° C.). Also, in the present invention, the value of resistivity (10⁷ Ωcm-10¹¹ Ωcm) of the semi-insulating film forming the gate insulating film is a value measured with the semi-insulating film sandwiched between two electrodes under the condition that the current density of the current flow between the electrodes is 6.25×10⁻⁴ (A/cm²).

It has also proved that by virtue of the feature that the resistivity of the semi-insulating film forming the gate insulating film is 10⁷ Ωcm or more, the gate leak current can be reduced as compared with cases where the resistivity of the gate insulating film is less than 10⁷ Ωcm.

The gate leak current mentioned above is given by a value of gate leak current measured under the conditions of 0 V applied to the source electrode, 600 V applied to the drain electrode, and −10 V applied to the gate electrode at normal temperature (25° C.)

In a field-effect transistor to one embodiment,

the nitride semiconductor layer is a GaN-based semiconductor layer.

According to this embodiment, the GaN-based semiconductor layer makes it possible to obtain large band gap energy and yet excellent thermal resistance that enables operations at high temperature, as compared with gallium arsenide (GaAs)-based materials.

A field-effect transistor according to one embodiment further comprises:

an insulating film formed between the source electrode and the drain electrode on the nitride semiconductor layer and serving for suppressing current collapse.

According to this embodiment, the insulating film makes it possible to suppress current collapse. The above-mentioned current collapse, which has been an issue particularly in GaN-based semiconductor devices, is a phenomenon that the ON-resistance of a transistor in high-voltage operation becomes considerably higher than the ON-resistance of the transistor in low-voltage operation.

In another aspect of the invention, there is provided a field-effect transistor manufacturing method comprising:

forming a source electrode and a drain electrode, at least partly, on a nitride semiconductor layer or within the nitride semiconductor layer, with a distance provided between those electrodes;

forming a gate insulating film by a semi-insulating film having a resistivity of 10⁷ Ωcm to 10¹¹ Ωcm between the source electrode and the drain electrode and on the nitride semiconductor layer; and

forming a gate electrode on the gate insulating film.

According to the field-effect transistor manufacturing method of this invention, since the gate insulating film is formed by a semi-insulating film having a resistivity of 10⁷ Ωcm to 10¹¹ Ωcm, the withstand voltage can be improved remarkably as compared with cases where the resistivity of the gate insulating film is over 10¹¹ Ωcm, and moreover the gate leak current can be reduced as compared with cases where the resistivity of the gate insulating film is under 10⁷ Ωcm.

In another aspect of the invention, there is provided a field-effect transistor manufacturing method comprising:

forming a first insulating film for suppressing current collapse on a nitride semiconductor layer;

removing a predetermined region of the first insulating film by etching so that a predetermined region of the nitride semiconductor layer is exposed;

forming a second insulating film on the first insulating film and on the nitride semiconductor layer exposed from the first insulating film;

removing a predetermined region of the second insulating film by etching so that the predetermined region of the nitride semiconductor layer is exposed;

forming a gate insulating film by a semi-insulating film having a resistivity of 10⁷ Ωcm to 10¹¹ Ωcm on the second insulating film and on the predetermined region of the nitride semiconductor layer exposed from the second insulating film; and

forming a gate electrode by vapor depositing a gate metal on the gate insulating film.

According to the field-effect transistor manufacturing method of this invention, the first, second insulating films are formed and etched in order, and thereafter the gate insulating film is formed. Therefore, the step of etching the second insulating film to form the opening for the gate electrode in the second insulating film is performed before the formation of the gate insulating film. Thus, the step of etching the second insulating film does not need to be performed after the formation of the gate insulating film, so that variations in the film thickness of the gate insulating film due to the etching process of the second insulating film can be avoided. Since the film thickness of the gate insulating film is an extremely important factor that defines the threshold value, it is strongly desired to suppress variations in the film thickness of the gate insulating film.

According to the field-effect transistor manufacturing method of the invention, the film thickness of the gate insulating film can be set with high precision, so that a stable threshold voltage can be obtained.

Also according to the field-effect transistor manufacturing method of the invention, since the gate insulating film is formed by a semi-insulating film having a resistivity of 10⁷ Ωcm to 10¹¹ Ωcm, the withstand voltage can be improved remarkably as compared with cases where the resistivity of the gate insulating film is over 10¹¹ Ωcm, and moreover the gate leak current can be reduced, as described above.

Also, the first insulating film makes it possible to suppress current collapse. The above-mentioned current collapse, which has been an issue particularly in GaN-based semiconductor devices, is a phenomenon that the ON-resistance of a transistor in high-voltage operation becomes considerably higher than the ON-resistance of the transistor in low-voltage operation. The first insulating film is formed by, for example, a Si-rich SiN film. The Si-rich SiN film is a SiN film larger in silicon Si ratio than stoichiometric silicon nitride films. Also, the second insulating film formed on the first insulating film makes it possible to further reduce the gate leak current. This second insulating film is formed by, for example, a stoichiometric silicon nitride film.

### Advantageous Effects of Invention

According to the field-effect transistor of this invention, it has proved that the withstand voltage can be considerably improved by the feature that the resistivity of the semi-insulating film forming the gate insulating film is 10¹¹ Ωcm or less, as compared with cases where the resistivity of the gate insulating film is over 10¹¹ Ωcm.

### BRIEF DESCRIPTION OF DRAWINGS

FIG. 1 is a sectional view showing a GaN-based HFET according to a first embodiment of the field-effect transistor of the invention;

FIG. 2A is a sectional view for explaining a manufacturing step of the GaN-based HFET of the first embodiment;

FIG. 2B is a sectional view for explaining a step subsequent to the step of FIG. 2A;

FIG. 2C is a sectional view for explaining a step subsequent to the step of FIG. 2B;

FIG. 3 is a characteristic chart showing a relationship between resistivity and withstand voltage of the gate insulating film;

FIG. 4 is an I-V characteristic chart showing a characteristic K1 representing variations in current density due to variations in the electric field applied to a semi-insulating film forming the gate insulating film provided in the first embodiment, and a characteristic K2 representing variations in resistivity due to variations in the applied electric field;

FIG. 5 is an I-V characteristic chart showing a characteristic K101 representing variations in current density due to variations in the electric field applied to a high-insulating film (SiO₂), and a characteristic K102 representing variations in resistivity due to variations in the electric field;

FIG. 6 is a sectional view showing a GaN-based HFET according to a second embodiment of the field-effect transistor of the invention;

FIG. 7A is a sectional view for explaining a manufacturing step of the GaN-based HFET of the first embodiment;

FIG. 7B is a sectional view for explaining a step subsequent to the step of FIG. 7A;

FIG. 7C is a sectional view for explaining a step subsequent to the step of FIG. 7B;

FIG. 7D is a sectional view for explaining a step subsequent to the step of FIG. 7C.

### DESCRIPTION OF EMBODIMENTS

Hereinbelow, the present invention will be described in detail by way of embodiments thereof illustrated in the accompanying drawings.

### First Embodiment

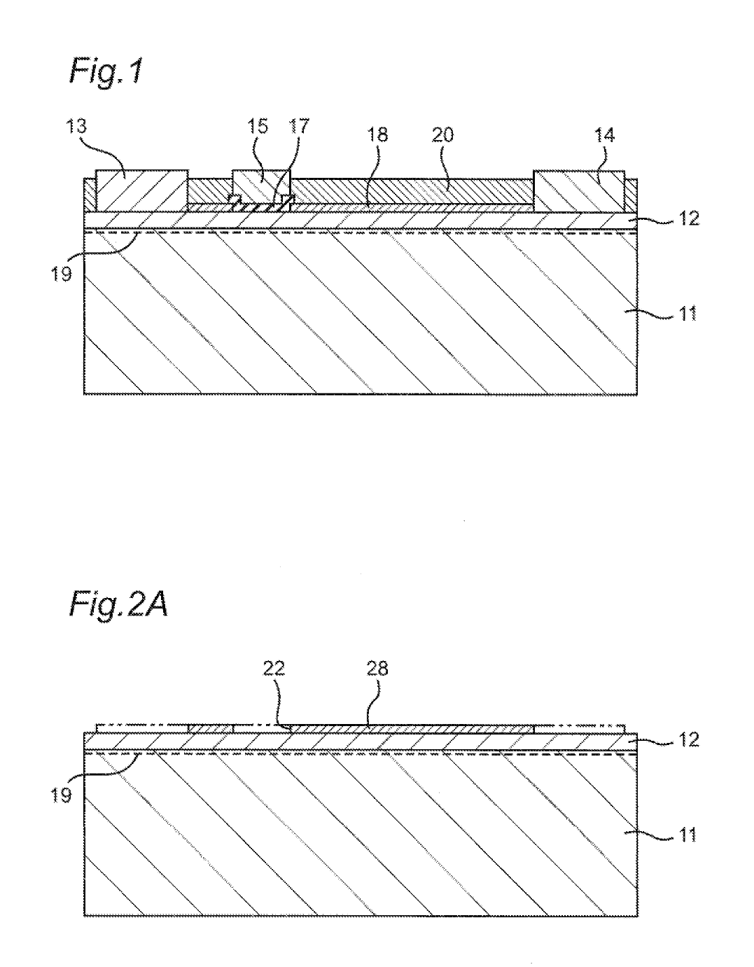

FIG. 1 is a sectional view showing a normally-ON type GaN-based HFET (Heterojunction Field-Effect Transistor) according to a first embodiment of the field-effect transistor of the invention.

In the GaN-based HFET of this first embodiment, as shown in FIG. 1, an undoped GaN layer 11 and an undoped AlGaN layer 12 are formed in order on a Si substrate (not shown). A 2DEG (2-Dimensional Electron Gas) 19 is generated at an interface between the undoped GaN layer 11 and the undoped AlGaN layer 12. The undoped GaN layer 11 and the undoped AlGaN layer 12 constitute a nitride semiconductor multilayered body. The substrate is not limited to a Si substrate and may be a sapphire substrate or SiC substrate, where a nitride semiconductor layer may be grown on the sapphire substrate or SiC substrate. A nitride semiconductor layer may be grown on a substrate formed of a nitride semiconductor such as when an AlGaN layer is grown on a GaN substrate. Also, a buffer layer may be formed between the substrate and the layers as required. An AlN layer having a layer thickness of 1 nm may also be formed between the undoped GaN layer 11 and the undoped AlGaN layer 12.

On the undoped AlGaN layer 12, a source electrode 13 and a drain electrode 14 are formed with a predetermined distance provided therebetween. A gate electrode 15 is formed on one side closer to the source electrode 13 between the source electrode 13 and the drain electrode 14 on the undoped AlGaN layer 12. In this case, with the undoped AlGaN layer 12 set to a thickness of 10 nm as an example, the source electrode 13 and the drain electrode 14 are annealed so as to be ohmic-contactable. Alternatively, it is also possible that with the undoped AlGaN layer 12 set to a thickness of 30 nm as an example, ohmic-contact portion of the undoped AlGaN layer 12 is preparatorily Si doped so as to be formed into the n-type and enabled to make ohmic contact of the electrodes. Moreover, it is further allowable that recesses are formed beforehand at portions of the undoped AlGaN layer 12 under the source electrode and the drain electrode and then the source electrode and the drain electrode are subjected to vapor deposition and annealing so as to be ohmic-contactable.

As shown in FIG. 1, a gate insulating film 17 is formed between the gate electrode 15 and the undoped AlGaN layer 12. This gate insulating film 17 is provided by a Si-rich silicon nitride film as a semi-insulating film as an example. The Si-rich silicon nitride film is a SiN film larger in silicon Si ratio than a stoichiometric silicon nitride film in which Si:N=0.75:1. For example, the Si—N composition ratio is Si:N=1.1-1.9:1. As a preferred example, the Si—N composition ratio is Si:N=1.3-1.5:1.

Also, a protective film 18 is formed between the gate insulating film 17 and the source electrode 13 on the undoped AlGaN layer 12 as well as between the gate insulating film 17 and the drain electrode 14 on the undoped AlGaN layer 12. This protective film 18, which is an insulating film for suppressing current collapse, is formed by a Si-rich silicon nitride film as an example.

Also, a process insulating film 20 is formed between the gate insulating film 17 and the source electrode 13 on the protective film 18 as well as between the gate insulating film 17 and the drain electrode 14 on the protective film 18. This process insulating film 20 is formed by a stoichiometric silicon nitride film in which Si:N=0.75:1 as an example.

In this first embodiment, as an example, the film thickness of the gate insulating film 17 is set to 20 nm, the film thickness of the protective film 18 is set to 30 nm, and the film thickness of the process insulating film 20 is set to 150 nm.

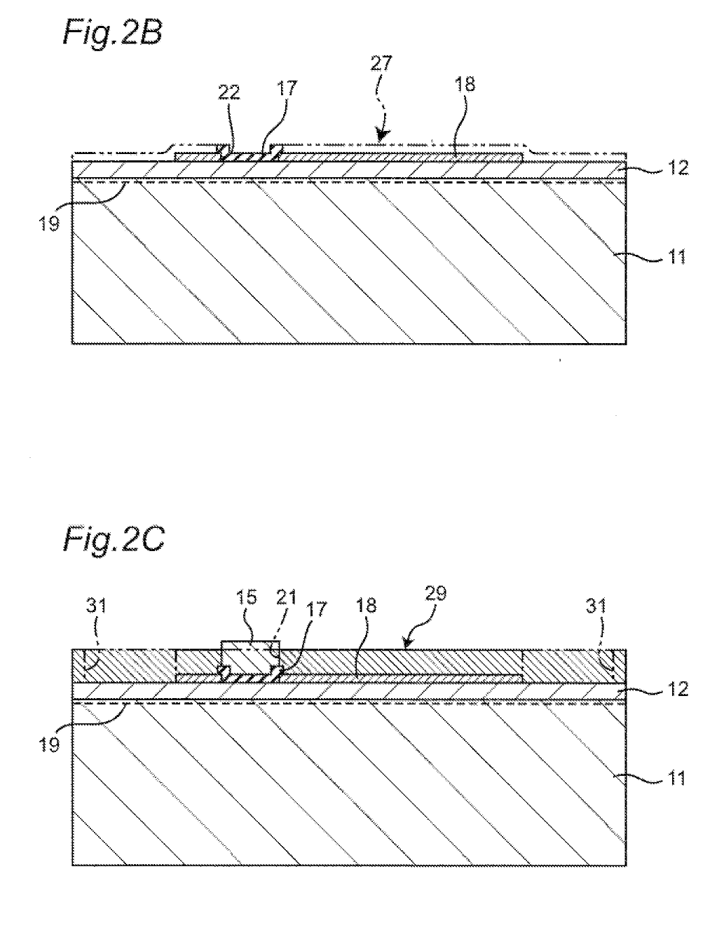

Next, a manufacturing method of the above-described GaN-based HFET will be described below with reference to FIGS. 2A to 2C in order.

First, as shown in FIG. 2A, an undoped GaN layer 11 and an undoped AlGaN layer 12 are formed in order on an unshown Si substrate by using MOCVD (Metal Organic Chemical Vapor Deposition). These undoped GaN layer 11 and undoped AlGaN layer 12 constitute a nitride semiconductor multilayered body.

Next, as shown in FIG. 2A, a silicon nitride film forming a protective film 18 is formed on the undoped AlGaN layer 12 by using plasma CVD process. Although the growth temperature for the silicon nitride film 28 forming the protective film 18 is set to 225° C. as an example in this case, yet the temperature may be set within a range of 200° C.-400° C. Also, although the film thickness of the silicon nitride film 28 forming the protective film 18 is set to 30 nm as an example, yet the film thickness may be set within a range of 20 nm-250 nm.

The gas flow ratio during the formation of the silicon nitride film 28 by the plasma CVD process in this case is set to N₂/NH₃/SiH₄=300 sccm/40 sccm/35 sccm as an example. With this setting, it becomes possible to form a silicon nitride film 28 larger in silicon Si ratio than stoichiometric silicon nitride films. According to this silicon nitride film 28, current collapse can be suppressed to more extent in comparison to stoichiometric silicon nitride films. Also, the setting that the Si—N composition ratio of the silicon nitride film 28 forming the protective film 18 is Si:N=1.1-1.9:1 as an example is effective for suppression of current collapse, as compared with the stoichiometric silicon nitride film in which Si:N=0.75:1. The above-mentioned current collapse, which noticeably appears particularly in GaN-based semiconductor devices, is a phenomenon that the ON-resistance of a transistor in high-voltage operation becomes considerably higher than the ON-resistance of the transistor in low-voltage operation.

Next, a photoresist layer (not shown) is formed on the silicon nitride film 28 forming the protective film 18. Then, by exposure and development, portions of the photoresist layer in regions where a source electrode 13 and a drain electrode 14 are to be formed, as well as portions of the photoresist layer in regions where a gate insulating film 17 is to be formed, are removed. Then dry etching using the resulting photoresist layer as a mask is performed. As a result, as shown in FIG. 2A, portions of the silicon nitride film 28 forming the protective film 18 in regions where the source electrode 13 and the drain electrode 14 are to be formed, as well as in regions where the gate insulating film 17 is to be formed, are removed, so that the undoped AlGaN layer 12 is exposed in these regions.

Next, the silicon nitride film 28 forming the protective film 18 is heat treated. Conditions of this heat treatment in this case are set to a temperature of 500° C. and a time duration of 30 min. as an example. The temperature of the heat treatment may also be set within a range of 500° C.-700° C. as an example.

Thereafter, as shown in FIG. 2B, a silicon nitride film 27 as a semi-insulating film to serve as the gate insulating film 17 is formed on the protective film 18 by plasma CVD (Chemical Vapor Deposition) process. This silicon nitride film 27 forming the gate insulating film 17 is made larger in silicon Si ratio than stoichiometric silicon nitride films.

In this case, vapor deposition conditions of plasma CVD for the formation of the silicon nitride film 27 forming the gate insulating film 17 are set, as an example, to an RF power of 50 W, a SiH₄—NH₃ flow ratio (SiH₄/NH₃) of 0.92, a pressure of 0.7 Torr, and a substrate temperature of 225° C.

Next, patterning using resist is performed upon the silicon nitride nitride film 27 to leave portions of the silicon nitride film 27 covering the undoped AlGaN layer 12 exposed from an opening 22 as well as portions of the silicon nitride film 27 covering the protective film 18 around the opening 22. As a result, the gate insulating film 17 is formed as shown in FIG. 2B.

Next, as shown in FIG. 2C, a stoichiometric silicon nitride film 29 forming a process insulating film 20 is formed by plasma CVD process. Then, by photolithography and etching, an opening 21 is formed at portions where the gate electrode 15 is formed.

Thereafter, TiN is sputtered all over the stoichiometric silicon nitride film 29 and the gate insulating film 17. Then a resist pattern (not shown) is formed by photolithography over an electrode formation region where the gate electrode 15 is to be formed. With this resist pattern used as a mask, dry etching or wet etching is performed to remove the TiN film except for the electrode formation region. Whereby the gate electrode 15 consisting of a TiN electrode is formed as shown in FIG. 2C. The gate insulating film 17 is positioned under the gate electrode 15.

Next, by photolithography and etching, as shown in FIG. 2C, openings 31, 32 are formed at portions of the silicon nitride film 29 where the source electrode 13 and the drain electrode 14 are to be formed.

Next, photoresist (not shown) opened in regions where the source electrode 13 and the drain electrode 14 are to be formed (regions of the AlGaN layer 12 exposed from the openings 31, 32) is formed by photolithography. On this photoresist, Ti and Al are deposited in order, and the source electrode 13 and the drain electrode 14 each consisting Ti/Al electrode are formed on the exposed AlGaN layer 12 by lift-off as shown in FIG. 1. The Ti/Al electrode is an electrode of a multilayer structure in which a Ti layer and an Al layer are stacked in order. Next, the source electrode 13 and the drain electrode 14 are heat treated so as to be ohmic electrodes. Although conditions of this heat treatment (ohmic annealing) are set as 500° C. and 30 min. as an example in this case, yet the heat treatment conditions are not limited to this and, for example, the heat treatment temperature may be set within a range of 400° C.-600° C.

According to the GaN-based HFET of the first embodiment fabricated as shown above, resistivity ρ of the semi-insulating film forming the gate insulating film 17 was 3.9×10⁹ Ωcm. This value of resistivity ρ (3.9×10⁹ Ωcm) is a value measured with the semi-insulating film sandwiched between two electrodes under the condition that the current density of the current flow between the electrodes is 6.25×10⁻⁴ (A/cm²).

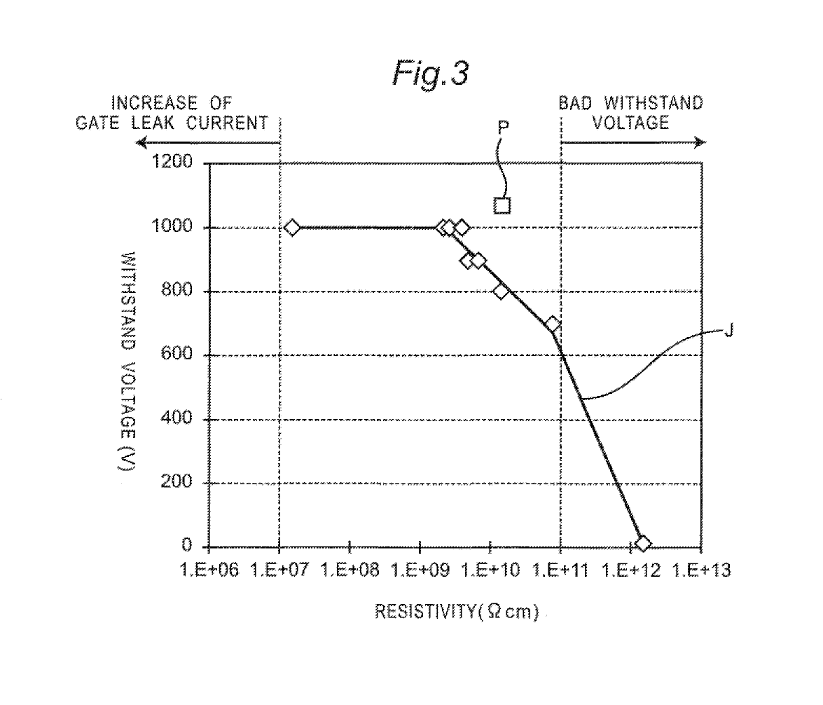

In this first embodiment, by virtue of the inclusion of the gate insulating film 17 provided by using a semi-insulating film with resistivity p=3.9×10⁹ Ωcm, a withstand voltage of 1000 V was obtained as shown in FIG. 3. It is noted that in FIG. 3, the horizontal axis represents resistivity (Ωcm), where scale divisions 1.E+06, 1.E+07, 1.E+08, 1.E+09, . . . , 1.E+13 represent 10⁶ (Ωcm), 10⁷ (Ωcm), 10⁸ (Ωcm), 10⁹ (Ωcm), . . . , 10¹³ (Ωcm), respectively. Also in FIG. 3, the withstand voltage in the vertical axis was given by voltage Vds (V) obtained immediately before occurrence of dielectric breakdown caused by increasing the voltage Vds between drain electrode and source electrode in steps of 50 V up to a dielectric breakdown under the conditions of 0 V applied to the source electrode and −10 V applied to the gate electrode at normal temperature (25° C.)

As shown in FIG. 3, it can be understood that the withstand voltage abruptly lowers as the resistivity of the gate insulating film goes beyond 1×10¹¹ Ωcm. It also proved that the gate leak current increases as the resistivity of the gate insulating film goes under 1×10⁷ Ωcm. This gate leak current is given by a value of gate leak current measured under the conditions of 0 V applied to the source electrode, 600 V applied to the drain electrode, and −10 V applied to the gate electrode at normal temperature (25° C.)

Also in FIG. 3, a plot P indicates withstand voltage and resistivity resulting when a semi-insulating film having a resistivity ρ of about 1×10¹⁰ (Ωcm) to serve as the gate insulating film 17 was subjected to 1-hour annealing at 680° C. As shown by the plot P, annealing (680° C., 1 hour) the gate insulating film 17 made it possible to improve the withstand voltage by 200 V or more with the same resistivity, as compared with a withstand voltage of 800 V obtained without annealing.

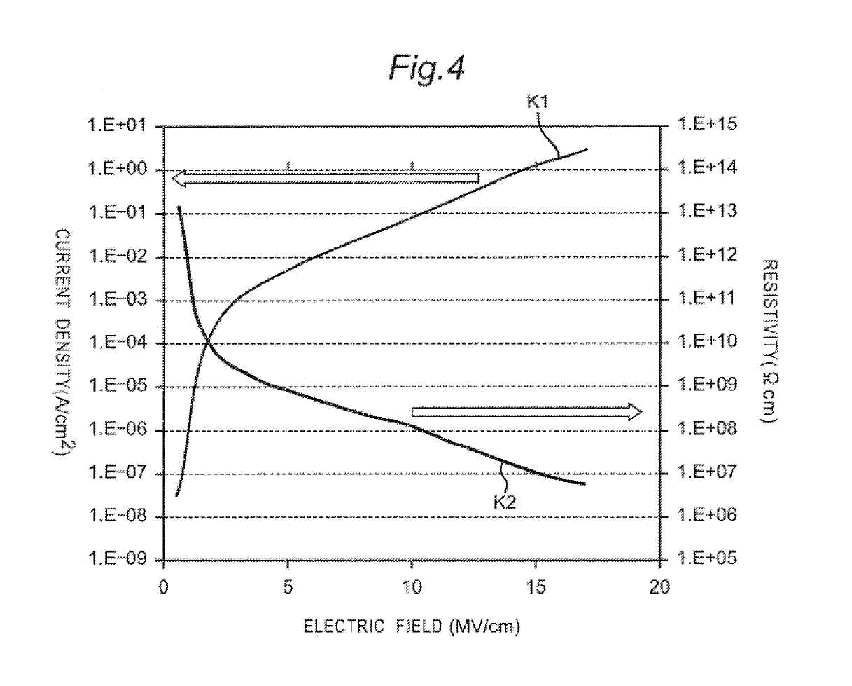

Next, an I-V characteristic K1 of the above-described semi-insulating film having resistivity ρ=3.9×10⁹ Ωcm will be described with reference to FIG. 4.

The I-V characteristic K1 of this semi-insulating film is a graph representing variations in current density of the current flow between the two electrodes due to variations in the electric field applied to the semi-insulating film sandwiched between the two electrodes. It is noted that in FIG. 4, the left-side vertical axis represents current density (A/cm²), where vertical-axis scale divisions 1.E-09, 1.E-08, 1.E-07, 1.E-06, . . . , 1.E+01 represent 10⁻⁹ (A/cm²), 10⁻⁸ (A/cm²), 10⁻⁷ (A/cm²), 10⁻⁶ (A/cm²), . . . , 10⁺¹ (A/cm²), respectively.

In this semi-insulating film, as shown in the I-V characteristic K1, whereas the current density increases generally in proportion to increases in the electric field in an electric field range of 5-15 (MV/cm), there occurs no dielectric breakdown even with the electric field beyond 15 (MV/cm).

Also, the characteristic K2 in FIG. 4 represents how the resistivity (Ωcm) represented by the right-side vertical axis varies relative to variations in the applied electric field of the horizontal axis. It is noted that in the right-side vertical axis of FIG. 4, scale divisions 1.E+05, 1.E+06, 1.E+07, 1.E+08, . . . , 1.E+15 represent 10⁵ (Ωcm), 10⁶ (Ωcm), 10⁷ (Ωcm), 10⁸ (Ωcm), . . . , 10¹⁵ (Ωcm), respectively. The resistivity (Qcm) in this characteristic K2 is given by a value obtained by dividing the electric field of the I-V characteristic K1 by the current density. As to this semi-insulating film, it can be understood that the resistivity in the characteristic K2 is decreased by increasing the applied electric field.

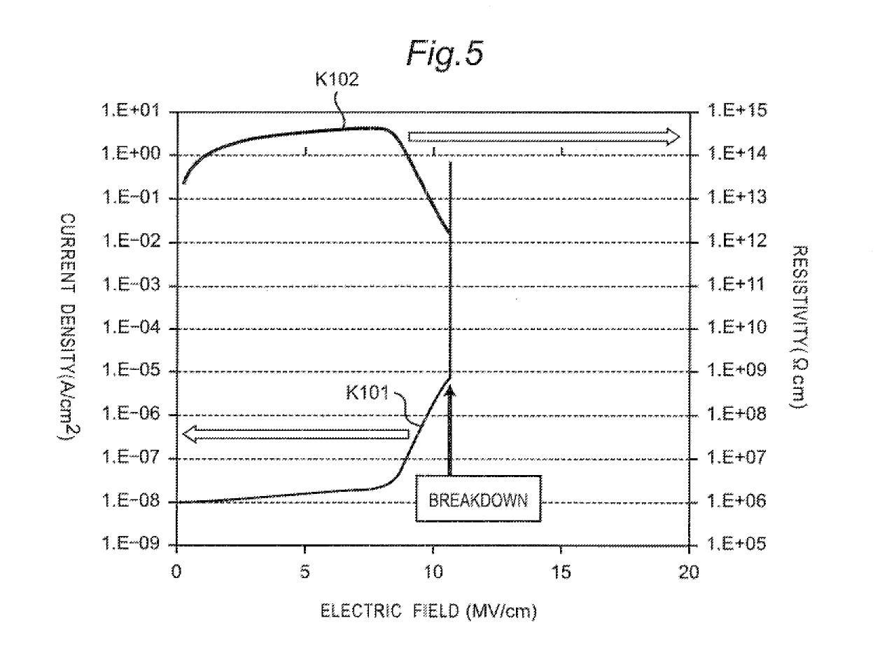

Next, an I-V characteristic K101 of a high-insulating film (SiO₂) is explained with reference to FIG. 5. The I-V characteristic K101 of this high-insulating film (SiO₂) is a graph representing variations in current density of the current flow between two electrodes, with the high-insulating film (SiO₂) sandwiched between the two electrodes, due to variations in the electric field applied to the high-insulating film (SiO₂). It is noted that in FIG. 5, the left-side vertical axis represents current density (A/cm²), where vertical-axis scale divisions 1.E-09, 1.E-08, 1.E-07, 1.E-06, . . . , 1.E+01 represent 10⁻⁹ (A/cm²), 10⁻⁸ (A/cm²), 10⁻⁷ (A/cm²), 10⁻⁶ (A/cm²), 10⁺¹ (A/cm²), respectively.

With this high-insulating film (SiO₂), as shown in the I-V characteristic K101, the current density abruptly increases as the applied electric field goes beyond 8 (MV/cm), and there occurs a dielectric breakdown with the applied electric field beyond 10 (MV/cm). Meanwhile, an I-V characteristic K102 of FIG. 5 represents how the resistivity (Ωcm) represented by the right-side vertical axis varies relative to variations in the applied electric field of the horizontal axis. The resistivity (Ωcm) in this characteristic K102 is given by a value obtained by dividing the electric field of the I-V characteristic K101 by the current density. It is noted that in the right-side vertical axis of FIG. 5, scale divisions 1.E+05, 1.E+06, 1.E+07, 1.E+08, . . . , 1.E+15 represent 10⁵ (Ωcm), 10⁶ (Ωcm), 10⁷ (Ωcm), 10⁸ (Ωcm), . . . , 10¹⁵ (Ωcm), respectively. As to this high-insulating film (SiO₂), although the resistivity does not largely change while the applied electric field is under 8 (MV/cm), yet the resistivity abruptly lowers as the applied electric field goes beyond 8 (MV/cm), and there occurs a dielectric breakdown with the applied electric field beyond 10 (MV/cm).

As shown above, with the high-insulating film (SiO₂), as shown in the characteristic K101 of FIG. 5, there occurs a dielectric breakdown with the applied electric field beyond 10 (MV/cm). In contrast to this, as shown in the characteristic K1 of FIG. 4, the semi-insulating film (resistivity ρ=3.9×10⁹ Ωcm) adopted as the gate insulating film 17 in this embodiment shows an I-V characteristic that the current density increases in proportion to increases in the applied electric field and there occurs no dielectric breakdown even with the applied electric field beyond 15 (MV/cm).

Thus, it has proved that as in the GaN-based HFET of this embodiment, in which a semi-insulating film having a resistivity of 3.9×10⁹ Ωcm when the current density is 6.25×10⁴ (A/cm²) is adopted as the gate insulating film 17, the withstand voltage can be improved remarkably, as compared with the case where a high-insulating film (SiO₂) having a resistivity over 1×10¹² (Ωcm) is adopted as the gate insulating film.

Also, as shown in FIG. 3 described before, by the setting that the resistivity of the semi-insulating film as the gate insulating film is within a range of 10⁷ Ωcm-10¹¹ Ωcm, the withstand voltage can be improved remarkably as compared with cases where the resistivity of the gate insulating film is over 10¹¹ Ωcm, and moreover the gate leak current can be reduced as compared with cases where the resistivity of the gate insulating film is under 10⁷ Ωcm.

### Second Embodiment

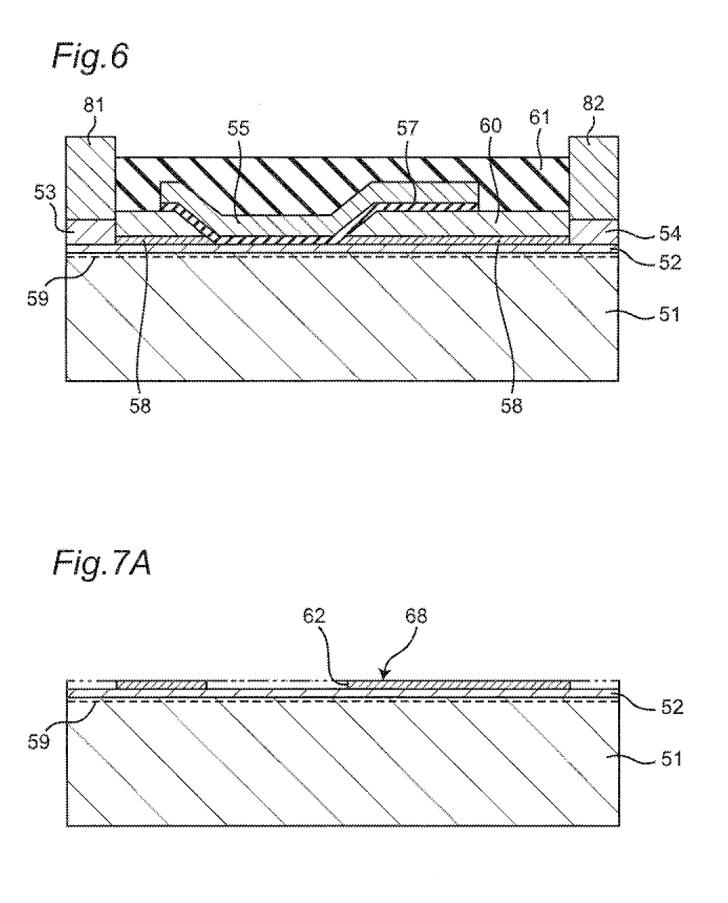

FIG. 6 is a sectional view showing a normally-ON type GaN-based HFET (Heterojunction Field Effect Transistor) according to a second embodiment of the field-effect transistor of the invention.

In the GaN-based HFET of this second embodiment, as shown in FIG. 6, an undoped GaN layer 51 and an undoped AlGaN layer 52 are formed in order on a Si substrate (not shown). A 2DEG (2-Dimensional Electron Gas) 59 is generated at an interface between the undoped GaN layer 51 and the undoped AlGaN layer 52. The undoped GaN layer 51 and the undoped AlGaN layer 52 constitute a nitride semiconductor multilayered body.

On the undoped AlGaN layer 52, a source electrode 53 and a drain electrode 54 are formed with a predetermined distance provided therebetween. A gate electrode 55 is formed on one side closer to the source electrode 53 between the source electrode 53 and the drain electrode 54 on the undoped AlGaN layer 52. In this case, with the undoped AlGaN layer 52 set to a thickness of 10 nm as an example, the source electrode 53 and the drain electrode 54 are annealed so as to be ohmic-contactable. Alternatively, it is also possible that with the undoped AlGaN layer 52 set to a thickness of 30 nm as an example, ohmic-contact portion of the undoped AlGaN layer 52 is preparatorily Si doped so as to be formed into the n-type and enabled to make ohmic contact of the electrodes. Moreover, it is further allowable that recesses are formed beforehand at portions of the undoped AlGaN layer 52 under the source electrode and the drain electrode and then the source electrode and the drain electrode are subjected to vapor deposition and annealing so as to be made ohmic-contactable.

In this second embodiment, as shown in FIG. 6, a gate insulating film 57 is formed between the gate electrode 55 and the undoped AlGaN layer 52. Also, a protective film 58 as a first insulating film is formed between the gate insulating film 57 each of the source electrode 53 and the drain electrode 54 on the undoped AlGaN layer 52, where the gate insulating film 57 is sandwiched between the gate electrode 55 and the undoped AlGaN layer 52. This protective film 58, which is formed by a Si-rich silicon nitride film as an example, is an insulating film for suppressing current collapse. This Si-rich silicon nitride film is a SiN film larger in silicon

Si ratio than stoichiometric silicon nitride films. For example, the Si—N composition ratio is Si:N=1.1-1.9:1. As a preferred example, the Si—N composition ratio is Si:N=1.3-1.5:1.

Also in this second embodiment, a process insulating film 60 as a second insulating film is formed on the protective film 18. The gate insulating film 57 and the gate electrode 55 are formed on the process insulating film 60. Also, an interlayer insulating film 61 is formed on the gate electrode 55 and the gate insulating film 57. Further, power-feeding metals 81, 82 are formed on the source electrode 53 and the drain electrode 54.

In this second embodiment, as an example, the film thickness of the gate insulating film 57 is set to 20 nm, the film thickness of the protective film 58 is set to 30 nm, and the film thickness of the process insulating film 60 is set to 150 nm.

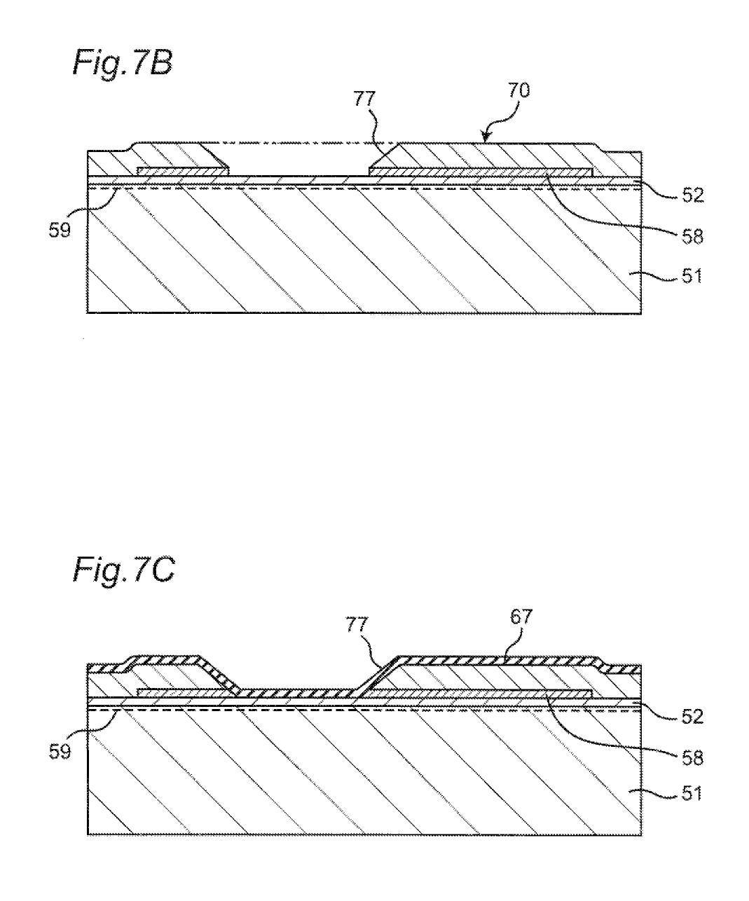

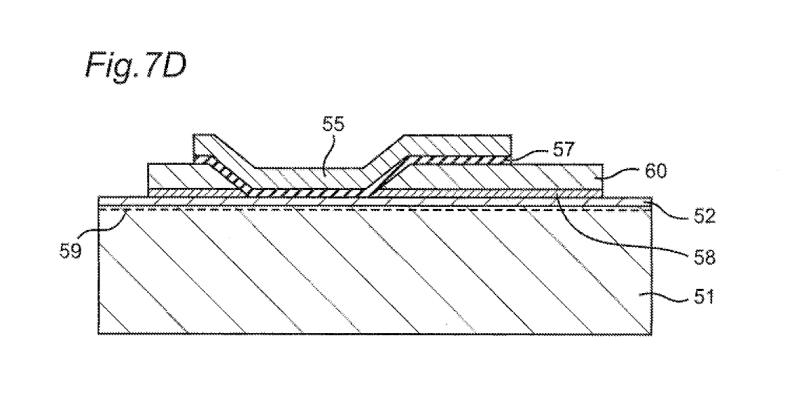

Next, a manufacturing method of the above-described GaN-based HFET will be described below with reference to FIGS. 7A to 7D in order.

First, as shown in FIG. 7A, an undoped GaN layer 51 and an undoped AlGaN layer 52 are formed in order on an unshown Si substrate by using MOCVD (Metal Organic Chemical Vapor Deposition). These undoped GaN layer 51 and undoped AlGaN layer 52 constitute a compound semiconductor multilayered body. The substrate is not limited to a Si substrate and may be a sapphire substrate or SiC substrate, where a nitride semiconductor layer may be grown on the sapphire substrate or SiC substrate. A nitride semiconductor layer may be grown on a substrate formed of a nitride semiconductor such as when an AlGaN layer is grown on a GaN substrate. Also, a buffer layer may be formed between the substrate and the layers as required.

Next, as shown in FIG. 7A, a silicon nitride film 68 forming a protective film 58 as a first insulating film is formed on the undoped AlGaN layer 52 by using plasma CVD process. Although the growth temperature for the silicon nitride film 68 forming the protective film 58 is set to 225° C. as an example in this case, yet the temperature may be set within a range of 200° C.-400° C. Also, although the film thickness of the silicon nitride film 68 forming the protective film 58 is set to 30 nm as an example, yet the film thickness may be set within a range of 20 nm-250 nm.

The gas flow ratio during the formation of the silicon nitride film 68 by the plasma CVD process in this case is set to N₂/NH₃/SiH₄=300 sccm/40 sccm/35 sccm as an example. With this setting, it becomes possible to form a silicon nitride film 68 larger in silicon Si ratio than stoichiometric silicon nitride films. According to this silicon nitride film 68, current collapse can be suppressed to more extent in comparison to stoichiometric silicon nitride films. Also, the setting that the Si—N composition ratio of the silicon nitride film 68 forming the protective film 58 as the first insulating film is Si:N=1.1-1.9:1 as an example is effective for suppression of current collapse, as compared with the stoichiometric silicon nitride film in which Si:N=0.75:1. The above-mentioned current collapse, which noticeably appears particularly in GaN-based semiconductor devices, is a phenomenon that the ON-resistance of a transistor in high-voltage operation becomes considerably higher than the ON-resistance of the transistor in low-voltage operation.

Next, a photoresist layer (not shown) is formed on the silicon nitride film 68 forming the protective film 58. Then, by exposure and development, portions of the photoresist layer in regions where a source electrode 53 and a drain electrode 54 are to be formed, as well as portions of the photoresist layer in regions where a gate insulating film 57 is to be formed, are removed. Then dry etching using the resulting photoresist layer as a mask is performed. As a result, as shown in FIG. 7A, the undoped AlGaN layer 52 is exposed in regions of the silicon nitride film 68 (which forms the protective film 58 as the first insulating film) where the source electrode 53, the drain electrode 54 and the gate insulating film 57 are to be formed.

Next, the silicon nitride film 68 forming the protective film 58 as the first insulating film is heat treated. Conditions of this heat treatment in this case are set to a temperature of 500° C. and a time duration of 30 min. as an example. The temperature of the heat treatment may also be set within a range of 500° C.-700° C. as an example.

Thereafter, as shown in FIG. 7B, a silicon nitride film 70 forming a process insulating film 60 as a second insulating film is formed on the undoped AlGaN layer exposed from the protective film 58 by plasma CVD (Chemical Vapor Deposition) process. This silicon nitride film 70 forming the process insulating film 60 is given by a stoichiometric silicon nitride film. Subsequently, a mask by photoresist is formed by photolithography, and the silicon nitride film 70 forming the process insulating film 60 as the second insulating film is isotropically etched by wet etching. As a result, as shown in FIG. 7B, regions of the silicon nitride film 70 where the gate electrode 55 and the gate insulating film 57 are to be formed are removed, so that an opening 77 tapered toward the AlGaN layer 52 is formed.

Next, as shown in FIG. 7C, a silicon nitride film 67 as a semi-insulating film to serve as the gate insulating film 57 is formed by plasma CVD (Chemical Vapor Deposition) process on the process insulating film 60 as the second insulating film and on the AlGaN layer 52 exposed from the opening 77 of the process insulating film 60. This silicon nitride film 67 as the gate insulating film 57 is made larger in silicon Si ratio than stoichiometric silicon nitride films.

In this case, vapor deposition conditions of plasma CVD for the formation of the silicon nitride film 67 forming the gate insulating film 57 are set, as an example, to an RF power of 50 W, a SiH₄—NH₃ flow ratio (SiH₄/NH₃) of 0.92, a pressure of 0.7 Torr, and a substrate temperature of 225° C.

Thereafter, TiN is sputtered all over the silicon nitride film 67, and a resist pattern (not shown) is formed by photolithography over an electrode formation region where the gate electrode 55 is to be formed. With this resist pattern used as a mask, dry etching or wet etching is performed to remove the TiN film except for the electrode formation region. As a result the gate electrode 55 consisting of a TiN electrode is formed as shown in FIG. 7D. Just under the gate electrode 55, the silicon nitride film 67 to serve as the gate insulating film 57 is positioned.

Next, a resist pattern (not shown) is formed on the gate electrode 55. With this resist pattern used as a mask, the silicon nitride film 67 in regions other than the gate electrode 55 is etched to form the gate insulating film 57.

Next, a resist pattern (not shown) opened in regions where the source electrode 53 and the drain electrode 54 are to be formed is formed by photolithography. With this resist pattern used as a mask, the silicon nitride film 70 is etched to form the process insulating film 60.

Next, photoresist (not shown) opened in regions where the source electrode 53 and the drain electrode 54 are to be formed (regions of the exposed AlGaN layer 52) is formed by photolithography. On this photoresist, Ti and Al are deposited in order, and the source electrode 53 and the drain electrode 54 each consisting Ti/Al electrode are formed on the exposed AlGaN layer 52 by lift-off as shown in FIG. 6. The Ti/Al electrode is an electrode of a multilayer structure in which a Ti layer and an Al layer are stacked in order. Next, the source electrode 53 and the drain electrode 54 are heat treated so as to be ohmic electrodes. Although conditions of this heat treatment (ohmic annealing) are set as 500° C. and 30 min. as an example in this case, yet the heat treatment conditions are not limited to this and, for example, the heat treatment temperature may be set within a range of 400° C.-600° C.

Next, a stoichiometric silicon nitride film to serve as the interlayer insulating film 61 is formed by plasma CVD process, and flattened by CMP (Chemical Mechanical Polishing) process or other like process. Next, photoresist (not shown) opened in regions on the source electrode 53 and the drain electrode 54 is formed. On this photoresist, power-feeding metals are deposited in order to form the power-feeding metals 81, 82. For the power-feeding metals, for example, Al, Cu and the like are used.

According to the GaN-based HFET of the second embodiment fabricated as shown above, resistivity ρ of the semi-insulating film forming the gate insulating film 57 was 3.9×10⁹ Ωcm. This value of resistivity ρ (3.9×10⁹ Ωcm) is a value measured with the semi-insulating film sandwiched between two electrodes under the condition that the current density of the current flow between the electrodes is 6.25×10⁻⁴ (A/cm²). The I-V characteristic of this semi-insulating film is similar to the I-V characteristic K1 shown in FIG. 4 described before.

In this second embodiment, by virtue of the inclusion of the gate insulating film 57 provided by using a semi-insulating film with resistivity ρ=3.9×10⁹ Ωcm, a withstand voltage of 1000 V was obtained as shown in FIG. 3.

Thus, according to this second embodiment, the resistivity of the semi-insulating film forming the gate insulating film 57 is 3.9×10⁹ Ωcm, and moreover the resistivity of the semi-insulating film is within a range of 10⁷ Ωcm to 10¹¹ Ωcm. As a result, as described before, the withstand voltage can be improved remarkably, as compared with cases where the resistivity of the gate insulating film is over 10¹¹ Ωcm. Furthermore, the gate leak current can be reduced as compared with cases where the resistivity of the gate insulating film is under 10⁷ Ωcm.

Further, according to the GaN-based HFET manufacturing method of the second embodiment described above with reference to FIGS. 7A to 7D in order, the protective film 58 as the first insulating film and the process insulating film 60 as the second insulating film are formed and etched in order, and thereafter the gate insulating film 57 is formed, as shown in FIGS. 7A to 7C. Therefore, since the gate insulating film 57 is deposited with the AlGaN layer 52 exposed and moreover no subsequent etching process is executed, the thickness of the gate insulating film 57 under the gate electrode 55 is determined by only the deposited film thickness of the gate insulating film 57 by plasma CVD process.

Accordingly, variations in the film thickness of the gate insulating film 57 due to etching process can be avoided. Thus, a stable threshold voltage can be obtained.

Furthermore, current collapse can be suppressed by the protective film 58 formed by the silicon-rich silicon nitride film. Also, the gate leak current can be further reduced by the process insulating film 60 formed by the stoichiometric silicon nitride film.

Although the semi-insulating film for forming the gate insulating film is provided by a SiN film larger in silicon Si ratio than stoichiometric silicon nitride films in the first, second embodiments, yet the semi-insulating film may also be provided by a SiON film. Besides, in the first, second embodiments, annealing the gate insulating film after the formation of the gate insulating film makes it possible to further improve the withstand voltage.

Also, although the GaN-based semiconductor multilayered body is composed of a GaN layer and an AlGaN layer in the first, second embodiments, yet the GaN-based semiconductor multilayered body may contain a GaN-based semiconductor layer expressed by AlₓIn_{y}Ga_{1-x-y}N (x≦0, y≦0, 0≦x+y≦1). That is, the GaN-based semiconductor multilayered body may contain AlGaN, GaN, InGaN or the like. Further, although the above embodiments have been described on a normally-ON type HFET, yet similar effects can be obtained even with the normally-OFF type ones.

Also, although the substrate is provided by using a Si substrate in the first, second embodiments, yet a sapphire substrate or SiC substrate may also be used therefor. Further, a nitride semiconductor layer may be grown on a substrate formed of a nitride semiconductor such as when an AlGaN layer is grown on the GaN substrate. Also, a buffer layer may be formed between the substrate and the layers as required. Also, a hetero-improvement layer formed of AlN having a layer thickness of about 1 nm as an example may be formed between the GaN layer 11, 51 and the AlGaN layer 12, 52. A GaN cap layer may also be formed on the AlGaN layer 12, 52. Although the gate electrode 15, 55 is formed of TiN in the above embodiments, yet the gate electrode may also be formed of WN. The gate electrode 15, 55 may also be formed of Pt/Au or Ni/Au. Further, as the gate electrode material, a material which, when joined with the nitride semiconductor, serves for Schottky junction may be used.

Also, although the source electrode 13, 53 and the drain electrode 14, 54 as the ohmic electrodes are provided by a Ti/Al electrode in which a Ti layer and an Al layer are stacked in order in the first, second embodiments, yet the source electrode and the drain electrode may also be provided by a Ti/Al/TiN electrode in which a Ti layer, an Al layer and a TiN layer are stacked in order. Instead of the Al layer, an AlSi layer or AlCu layer may be used. Further, the source electrode and the drain electrode may be Hf/Al electrodes. The source electrode and the drain electrode may also be those in which Ni/Au is stacked on Ti/Al or Hf/Al, or those in which Pt/Au is stacked on Ti/Al or Hf/Al, or those in which Au is stacked on Ti/Al or Hf/Al.

Although specific embodiments of the present invention have been described hereinabove, yet the invention is not limited to the above embodiments and may be carried out as they are changed and modified in various ways within the scope of the invention.

### REFERENCE SIGNS LIST

11, 51 undoped GaN layer
12, 52 undoped AlGaN layer
13, 53 source electrode
14, 54 drain electrode
15, 55 gate electrode
17, 57 gate insulating film
18, 58 protective film
19, 59 2-dimensional electron gas
20, 60 process insulating film
22, 62, 77 opening
27, 28, 68, 70 silicon nitride film
61 interlayer insulating film

1. A field-effect transistor comprising:
a nitride semiconductor layer;
a source electrode and a drain electrode which are formed, at least partly, on the nitride semiconductor layer or within the nitride semiconductor layer and which are disposed with a distance to each other;
a gate electrode formed on the nitride semiconductor layer and disposed between the source electrode and the drain electrode; and
a gate insulating film formed between the gate electrode and the nitride semiconductor layer, wherein
the gate insulating film is
a semi-insulating film having a resistivity of 10⁷ Ωcm to 10¹¹ Ωcm.

2. The field-effect transistor as claimed in claim 1, wherein
the nitride semiconductor layer is a GaN-based semiconductor layer.

3. The field-effect transistor as claimed in claim 1, further comprising:
an insulating film formed between the source electrode and the drain electrode on the nitride semiconductor layer and serving for suppressing current collapse.

4. A field-effect transistor manufacturing method comprising:
forming a source electrode and a drain electrode, at least partly, on a nitride semiconductor layer or within the nitride semiconductor layer, with a distance provided between those electrodes;
forming a gate insulating film by a semi-insulating film having a resistivity of 10⁷ Ωcm to 10¹¹ Ωcm between the source electrode and the drain electrode and on the nitride semiconductor layer; and
forming a gate electrode on the gate insulating film.

5. A field-effect transistor manufacturing method comprising:
forming a first insulating film for suppressing current collapse on a nitride semiconductor layer;
removing a predetermined region of the first insulating film by etching so that a predetermined region of the nitride semiconductor layer is exposed;
forming a second insulating film on the first insulating film and on the nitride semiconductor layer exposed from the first insulating film;
removing a predetermined region of the second insulating film by etching so that the predetermined region of the nitride semiconductor layer is exposed;
forming a gate insulating film by a semi-insulating film having a resistivity of 10⁷ Ωcm to 10¹¹ Ωcm on the second insulating film and on the predetermined region of the nitride semiconductor layer exposed from the second insulating film; and
forming a gate electrode by vapor depositing a gate metal on the gate insulating film.

6. The field-effect transistor as claimed in claim 2, further comprising:
an insulating film formed between the source electrode and the drain electrode on the nitride semiconductor layer and serving for suppressing current collapse.
